(19) United States
(12) Patent Application Publication
(10) Pub. No.: US 2026/0211156 A1
(43) Pub. Date: Jul. 23, 2026

(54) PROTECTIVE LAYER, METHOD OF MANUFACTURING THE SAME, DISPLAY DEVICE INCLUDING THE PROTECTIVE LAYER AND ELECTRONIC DEVICE INCLUDING THE DISPLAY DEVICE

(71) Applicant: Samsung Display Co., Ltd., Yongin-si (KR)

(72) Inventor: Taehee Kim, Yongin-si (KR)

(21) Appl. No.: 19/440,104

(22) Filed: Jan. 5, 2026

(30) Foreign Application Priority Data
Jan. 20, 2025 (KR) 10-2025-0008180

(51) Int. Cl. G02B 1/14; G02B 1/115; H10H 29/80; H10H 29/855; H10K 59/80

(52) U.S. Cl. CPC G02B 1/14; G02B 1/115; H10K 59/873; H10K 59/879; H10H 29/842; H10H 29/855

(57) ABSTRACT

A protective layer includes: a cover window; an anti-reflection layer on the cover window, the anti-reflection layer having a flat area having a first thickness and an open area having a second thickness that is smaller than the first thickness; and a planarization layer on the anti-reflection layer and filling the open area.

### CROSS-REFERENCE TO RELATED APPLICATION

This application claims priority to and the benefit of Korean Patent Application No. 10-2025-0008180, filed on Jan. 20, 2025, in the Korean Intellectual Property Office, the present disclosure of which is incorporated by reference herein in its entirety.

### BACKGROUND

### 1. Field

Aspects of embodiments of the present disclosure relate to a protective layer, a method of manufacturing the same, a display device including the protective layer, and an electronic device including the display device.

### 2. Description of the Related Art

A display device is manufactured by combining various components with each other. For example, the display device may include a display panel including a display element and a protective layer configured to protect the display panel. A protective layer may include an anti-reflection layer configured to reduce reflectance of light incident from the outside to improve visibility.

The anti-reflection layer may include a plurality of layers deposited by a method, such as sputtering, and foreign matter may be adsorbed thereto during a deposition process. When the foreign matter detaches, a part of the anti-reflection layer may be removed together with the foreign matter such that an area with a relatively higher reflectance of light may be formed.

### SUMMARY

Embodiments of the present disclosure include a protective layer in which glare, which is caused by an area of relatively high light reflectance due to an anti-reflection layer not being formed or being removed after being formed in some areas, is reduced, a method of manufacturing the protective layer, a display device including the protective layer, and an electronic device including the display device.

Additional aspects and features of the present disclosure will be set forth, in part, in the description that follows and, in part, will be apparent from the description or may be learned by practice of the described embodiments of the present disclosure.

According to an embodiment of the present disclosure, a protective layer includes a cover window, an anti-reflection layer on the cover window, the anti-reflection layer having a flat area having a first thickness and an open area having a second thickness that is smaller than the first thickness; and a planarization layer on the anti-reflection layer and filling the open area.

According to an embodiment, the protective layer may further include an anti-fingerprint layer on the planarization layer.

According to an embodiment, the planarization layer may be in direct contact with the anti-fingerprint layer.

According to an embodiment, an interval between the anti-reflection layer and the anti-fingerprint layer may be in a range of 60 nm to 120 nm.

According to an embodiment, the first thickness may be 250 nm or less.

According to an embodiment, the planarization layer may have a refractive index in a range of about 1.3 to about 1.6.

According to an embodiment, the planarization layer may include magnesium, silicon, calcium, or a combination thereof.

According to an embodiment, the anti-reflection layer may include a high-refractive-index layer and a low-refractive-index layer, which are alternately stacked on each other.

According to an embodiment, the anti-reflection layer may include a first high-refractive-index layer, a first low-refractive-index layer, and a second high-refractive-index layer, which are sequentially stacked in the flat area, and at least one of the first high-refractive-index layer, the first low-refractive-index layer, and the second high-refractive-index layer is not located in the open area.

According to an embodiment, the anti-reflection layer may include a first low-refractive-index layer, a first high-refractive-index layer, and a second low-refractive-index layer, which are sequentially stacked in the flat area, and at least one of the first low-refractive-index layer, the first high-refractive-index layer, and the second low-refractive-index layer is not located in the open area.

According to an embodiment, a refractive index of the planarization layer may be smaller than a refractive index of the high-refractive-index layer.

According to an embodiment, the high-refractive-index layer may have a refractive index of 1.7 or more.

According to an embodiment, the high-refractive-index layer may include titanium, aluminum, indium, or a combination thereof.

According to an embodiment, the low-refractive-index layer may have a refractive index of 1.6 or less.

According to an embodiment, the low-refractive-index layer may include an acrylic compound, silicon, magnesium, or a combination thereof.

According to an embodiment, a reflectance of light having a wavelength in a range of about 450 nm to about 700 nm incident on the open area may be 6% or less.

According to another embodiment of the present disclosure, a method of manufacturing a protective layer includes forming an anti-reflection layer by depositing an anti-reflection material on a cover window and forming a planarization layer on a flat area of the anti-reflection layer having a first thickness and in an open area in the anti-reflection layer having a second thickness that is smaller than the first thickness by a spray coating method.

According to another embodiment of the present disclosure, a display device includes a display panel and a protective layer on the display panel. The protective layer includes a cover window, an anti-reflection layer on the cover window, the anti-reflection layer having a flat area having a first thickness and an open area having a second thickness that is smaller than the first thickness; and a planarization layer on the anti-reflection layer and filling the open area.

According to an embodiment, display panel may be configured to emit light in a direction toward the protective layer.

According to another embodiment of the present disclosure, an electronic device includes the above-described display device and a processor configured to transmit signals to the display device.

According to an embodiment, the electronic device may be one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle instrument cluster, a vehicle center information display (CID), a vehicle head-up display, a room mirror display, a video wall, theater, or stadium screen including multiple displays tiled together, a light therapy device, and a signage.

### BRIEF DESCRIPTION OF THE DRAWINGS

The above and other aspects and features of embodiments of the present disclosure will be more apparent from the following description taken in conjunction with the accompanying drawings, in which:

FIG. 1 is a perspective view of a display device according to an embodiment;

FIG. 2 is a side view of a display device according to an embodiment;

FIG. 3 is a schematic cross-sectional view taken along the line I-I′ in FIG. 1;

FIG. 4 is a plan view of a display panel included in the display device shown in FIG. 3;

FIG. 5 is an equivalent circuit diagram of a pixel circuit included in the display panel shown in FIG. 4;

FIG. 6 is a schematic cross-sectional view taken along the line II-II′ in FIG. 4;

FIG. 7 is a cross-sectional view of a protective layer included in the display device shown in FIG. 3;

FIGS. 8A to 8F are cross-sectional views schematically showing steps of a process of adsorption and desorption of foreign matter during manufacturing of a protective layer according to an embodiment;

FIG. 9 is a graph showing reflectance with respect to wavelength of a protective layer according to an embodiment;

FIG. 10 is a graph showing reflectance of light having a wavelength of 550 nm of a protective layer according to an embodiment with respect to thickness of a planarization layer included in the protective layer;

FIG. 11 is a block diagram describing an electronic device including a display device according to an embodiment; and

FIG. 12 shows schematic diagrams of electronic devices according to various embodiments.

### DETAILED DESCRIPTION

Reference will now be made, in detail, to embodiments, examples of which are illustrated in the accompanying drawings. Accordingly, the present embodiments may have different forms and should not be construed as being limited to the descriptions set forth herein. Accordingly, embodiments are merely described below, by referring to the figures, to explain aspects and features of the present description.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof.

As the present disclosure below allows for various changes and numerous embodiments, particular embodiments will be illustrated in the drawings and described in detail in the written description. Aspects and features of the present disclosure and a method of achieving them will be apparent by referring to the embodiments described below in connection with the accompanying drawings. However, the present disclosure is not restricted by these embodiments and can be implemented in many different forms.

Throughout the specification, terms “first,” “second,” etc. may be used to distinguish one component from other components and, therefore, the components are not limited by these terms.

An expression used in the singular encompasses the expression of the plural unless it has a clearly different meaning in the context.

Throughout the specification, it is to be understood that the terms “comprise,” “include,” or “have” are intended to indicate the existence of elements disclosed in the specification and are not intended to preclude the possibility that one or more other elements may exist or may be added.

As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Throughout the specification, the term “A and/or B” may refer to either A or B, or both A and B. In addition, “at least one of A and B” may refer to either A or B, or both A and B.

As used herein, when one element such as layer, film, region, plate is referred to as being “on” another element, it may be “directly on” the other element, or intervening elements may also be present therebetween.

Throughout the specification, when a membrane, region, or element is referred to as being “connected to” another membrane, region, or element, they may be “directly connected to” and/or “indirectly connected” with an intervening membrane, region, or element therebetween. For example, when a membrane, region, or element is referred to as being “electrically connected to” another membrane, region, or element, they may be “directly, electrically connected to” and/or “indirectly, electrically connected” with an intervening membrane, region, or element therebetween.

As used herein, the x-axis, the y-axis and the z-axis are not limited to three axes of the rectangular coordinate system and may be interpreted in a broader sense. For example, the x-axis, the y-axis, and the z-axis may be orthogonal to each other but may not be orthogonal to one another facing different directions.

Hereinafter, embodiments will be described, in detail, with reference to the accompanying drawings. In the drawings, like reference numerals denote like elements or components having substantially same functions, and duplicate descriptions thereof will be omitted or only briefly repeated. Sizes of elements in the drawings may be exaggerated or reduced for convenience of explanation. For example, because sizes and thicknesses of components in the drawings may be arbitrarily illustrated for convenience of explanation, the following embodiments are not limited thereto.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

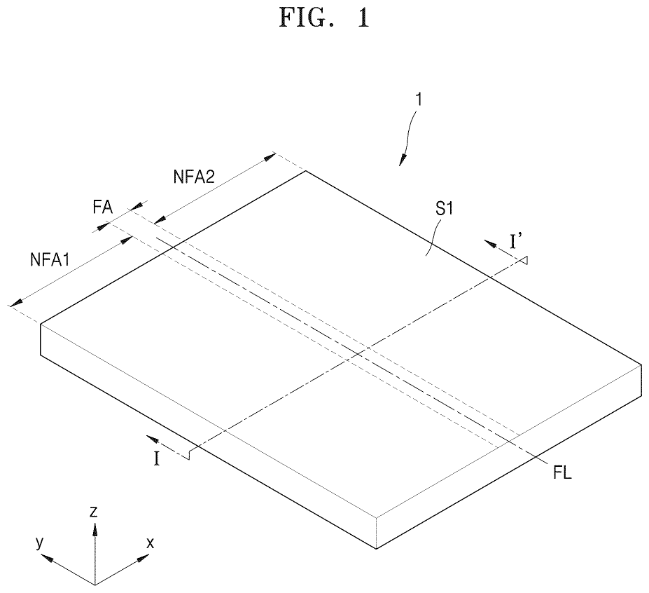

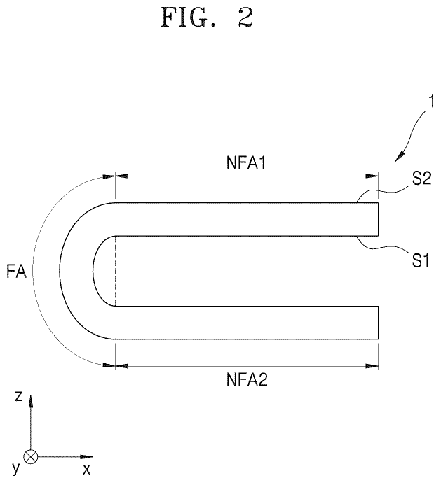

FIG. 1 is a perspective view of a display device 1 according to an embodiment, and FIG. 2 is a side view of the display device 1 shown in FIG. 1. FIG. 1 shows the display device 1 in an unfolded state, and FIG. 2 shows the display device 1 in a folded state. The x-axis direction refers to a width direction of the display device 1, the y-axis direction refers to a length direction of the display device 1, and the z-axis direction refers to a thickness direction of the display device 1. For convenience of explanation, a first surface S1 facing a direction in which the display device 1 provides (or emits) an image (i.e., the +z direction in FIG. 1) may be referred to as an upper surface, and a lower surface opposite to the first surface S1 may be referred to as a second surface S2, but the present disclosure is not limited thereto. For example, the display device 1 may also provide (or emit) an image on (or from) the second surface S2.

Referring to FIGS. 1 and 2, the display device 1 may display an image, such as a moving image and/or a still image. The display device 1 may have a polygonal shape, such as a rectangular shape. For example, the display device 1 may have a rectangular shape in which a width is smaller than a length or in which the width is greater than the length, or a square shape. In other embodiments, the display device 1 may have various shapes, such as a circular or oval shape.

The display device 1 may have the first surface S1 and the second surface S2 opposite to the first surface S1. The first surface S1 may be the upper surface of the display device 1 (e.g., in the +z direction). The second surface S2 may be the lower surface of the display device 1 (e.g., in the −z direction). The display device 1 may display an image on the first surface S1. For example, the first surface S1 may include (or may have) a display surface. The display device 1 may also display an image on the second surface S2.

The display device 1 may be folded (e.g., may be foldable). At least a part of the display device 1 may be flexible. The display device 1 may be folded by bending a flexible portion. The display device 1 may have an area that is foldable and another area adjacent to the foldable area that is non-foldable (e.g., is non-flexible or rigid). The term “non-foldable” means an area that cannot be folded and includes not only a case where the area cannot be folded due to low flexibility and rigidity but also a case where the area cannot be folded even through it is flexible. The display device 1 may display an image not only on the non-foldable area but also on the foldable area.

As shown in FIG. 1, the display device 1 may have a first non-foldable area NFA1, a second non-foldable area NFA2, and a foldable area FA. The first non-foldable area NFA1 and the second non-foldable area NFA2 may be areas that cannot be folded, and the foldable area FA may be an area that is flexible and can be folded.

The foldable area FA may extend in a direction crossing (e.g., intersecting) a virtual straight line connecting (or extending between) the first non-foldable area NFA1 and the second non-foldable area NFA2. For example, when the display device 1 is unfolded, the first non-foldable area NFA1 and the second non-foldable area NFA2 may be spaced apart from each other in a first direction (e.g., the x-axis direction). The foldable area FA may be arranged between the first non-foldable area NFA1 and the second non-foldable area NFA2. Specifically, the first non-foldable area NFA1 may be arranged adjacent to one side of the foldable area FA, and the second non-foldable area NFA2 may be arranged adjacent to the other side (e.g., the opposite side) of the foldable area FA. When the display device 1 is unfolded, the foldable area FA may extend in a second direction (e.g., the y-axis direction) crossing (e.g., intersecting) the first direction.

A folding line (or folding axis) FL may extend through the foldable area FA in the second direction (e.g., the y-axis direction), which is the extending direction of the foldable area FA. Accordingly, the display device 1 may be folded in the foldable area FA. The foldable area FA and the folding line FL of the foldable area FA may overlap an area where an image is displayed in the display device 1. When the display device 1 is folded, the area at where the image is displayed may be folded (e.g., the display device 1 may be in-folded).

FIG. 1 illustrates an embodiment in which the first non-foldable area NFA1 and the second non-foldable area NFA2 have areas equal or similar to each other and the display device 1 includes one foldable area FA for convenience of explanation, but the present disclosure is not limited thereto. For example, the first non-foldable area NFA1 and the second non-foldable area NFA2 may have different areas with respect to each other. In addition, the display device 1 may have a plurality of foldable areas FAs. In such an embodiment, a plurality of non-foldable areas may be arranged to be spaced apart from each other, and each of the plurality of foldable areas FAs may be arranged between the non-foldable areas. Each foldable area FA may be folded based on (e.g., may be folded about) the folding line FL, and a plurality of the folding lines FLs may be provided.

FIG. 1 shows an embodiment in which the folding line FL is located at the center of the foldable area FA and the foldable area FA is symmetrical with respect to the folding line FL, but the present disclosure is not limited thereto. For example, the folding line FL may be asymmetrically provided within the foldable area FA.

As shown in FIG. 2, the display device 1 may be folded such that the first surface S1 of the first non-foldable area NFA1 and the first surface S1 of the second non-foldable area NFA2 face each other about the folding line FL. For example, as the foldable area FA of the display device 1 is bent, the first surface S1 of the first non-foldable area NFA1 may be disposed to face the first surface S1 of the second non-foldable area NFA2. Although the display device 1 is folded, the foldable area FA may extend in a direction crossing (e.g., intersecting) a virtual straight line connecting the first non-foldable area NFA1 with the second non-foldable area NFA2. For example, when the display device 1 is folded, the foldable area FA may extend in a second direction (e.g., the y-axis direction) crossing (e.g., intersecting) a virtual straight line (e.g., a line parallel to the z-axis direction) connecting (or extending between) the first non-foldable area NFA1 and the second non-foldable area NFA2.

The foldable area FA may be unfolded after being folded. That is, the display device 1 may be a foldable display device. As used herein, the term “folded” does not mean that the shape is fixed but rather means that the shape is deformed from the original state thereof and includes folded, curved, and bended along a certain line (e.g., the folding line FL). Thus, although FIG. 2 shows an embodiment in which the first surface S1 of the first non-foldable area NFA1 and the first surface S1 of the second non-foldable area NFA2 are disposed parallel to each other and face each other, the present disclosure is not limited thereto. For example, the folding may occur such that the first surface S1 of the first non-foldable area NFA1 and the first surface S1 of the second non-foldable area NFA2 are arranged at a certain angle (e.g., an acute angle, a right angle, or an obtuse angle) with the foldable area FA located therebetween.

In addition, although FIG. 2 shows an embodiment in which the display device 1 is folded in an in-folding manner such that a part of the first surface S1 faces another part of the first surface S1, the present disclosure is not limited thereto. For example, the display device 1 may also be folded in an out-folding manner such that a part of the second surface S2 faces another part of the second surface S2. In other words, the display device 1 may be configured in the in-folding manner, in which portions of a display surface face each other when folded or in the out-folding manner, in which the display surface is exposed to the outside when folded. Hereinafter, an embodiment in which the display device 1 is folded in the in-folding manner will be described for convenience of explanation.

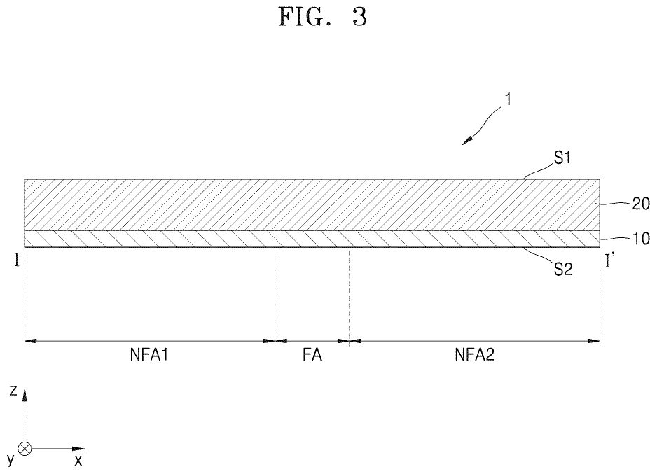

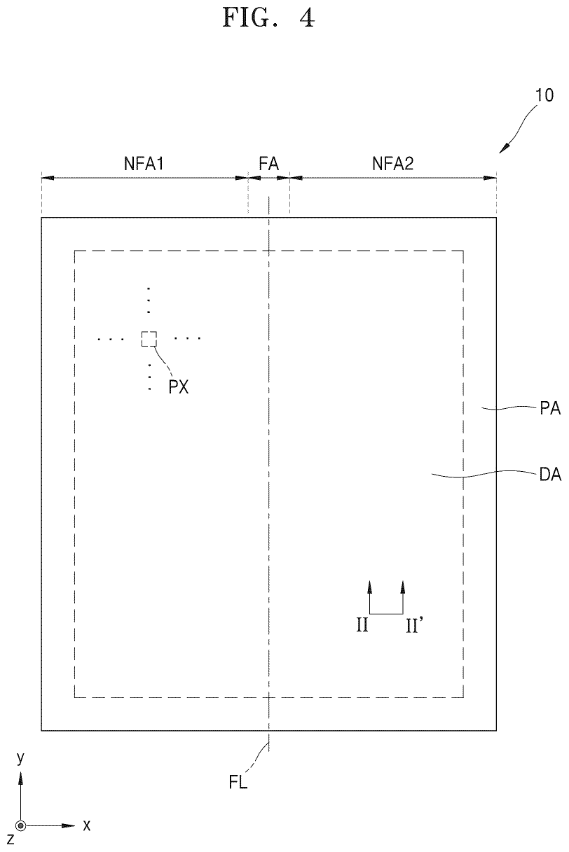

FIG. 3 is a schematic cross-sectional view taken along the line I-I′ in FIG. 1, and FIG. 4 is a plan view schematically illustrating a display panel 10 included in the display device 1 shown in FIG. 3. As shown in FIG. 3, the display device 1 may include the display panel 10 and a protective layer 20. Also, the display device 1 may further include various components in addition to the components illustrated in FIG. 3.

The display panel 10 may display an image. For example, the image provided by (e.g., emitted by) the display device 1 may be understood as being implemented by the display panel 10. The display panel 10 may include a plurality of display elements, and the plurality of display elements may emit red, green, or blue light. Therefore, the display panel 10 may display the image by light emitted from the plurality of display elements.

In an embodiment, the display element may be a light emitting diode (LED), such as an organic light emitting diode OLED including an organic emission layer. The light emitting diode (LED) may have a micro-scale or nano-scale size. For example, the light emitting diode may be a micro light emitting diode. In another embodiment, the light emitting diode may be a nanorod light emitting diode. The nanorod light emitting diode may include gallium nitride (GaN). In an embodiment, a color conversion layer may be disposed on a nanorod light emitting diode. The color conversion layer may include quantum dots. In another embodiment, the display element may be a quantum dot light emitting diode including a quantum dot emission layer. In another embodiment, the display element may be an inorganic light emitting diode including an inorganic semiconductor. Components included in the display panel 10 will be described below in more detail.

As described above, the display device 1 may have the first non-foldable area NFA1, the second non-foldable area NFA2, and the foldable area FA. Because the display device 1 includes the display panel 10, the display panel 10 may also have the first non-foldable area NFA1, the second non-foldable area NFA2, and the foldable area FA, as described above. Hereinafter, for convenience of explanation, the display panel 10 including the first non-foldable area NFA1, the second non-foldable area NFA2, and the foldable area FA will be described.

In the unfolded state, the first non-foldable area NFA1 and the second non-foldable area NFA2 of the display panel 10 may be arranged to be spaced apart from each other along the first direction (e.g., the x-axis direction). The foldable area FA may be arranged between the first non-foldable area NFA1 and the second non-foldable area NFA2 and may extend in a direction crossing (e.g., intersecting) a virtual straight line connecting (or extending between) the first non-foldable area NFA1 and the second non-foldable area NFA2. The folding line FL may be provided in the foldable area FA along the second direction, which is the extending direction of the foldable area FA (e.g., the y-axis direction). Accordingly, the display panel 10 may be folded in (or folded at) the foldable area FA.

As shown in FIG. 4, the display panel 10 may have a display area DA in which a plurality of pixels PXs are arranged and a peripheral area PA arranged at outer areas of (e.g., at or around a periphery of) the display area DA.

Each pixel PX of the display panel 10 is a region in which light of a certain color is emitted, and the display panel 10 may provide an image by using light emitted from the pixels PXs. For example, each pixel PX may emit red, green, or blue light. That is, one display element may correspond to one pixel.

The display area DA, as an area providing (or emitting) an image, may have a polygonal shape, such as a rectangular shape as shown in FIG. 4. For example, the display area DA may have a rectangular shape in which a width is greater than a length or in which the width is smaller than the length or a square shape. In other embodiments, the display area DA may have various shapes, such as a circular or oval shape.

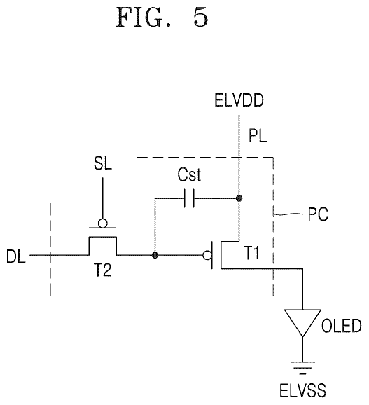

The peripheral area PA, as a non-display region not providing (or emitting) an image, may surround at least a part of the display area DA. Specifically, the pixels PXs are not arranged in the peripheral area PA, and components, such as drivers configured to supply electrical signals or power to the pixels PXs, may be arranged in the peripheral area PA. Pads may also be located in the peripheral area PA, and electronic devices, printed circuit boards, or the like may be electrically connected to these pads. The pads may be located in the peripheral area PA and spaced apart from each other, respectively, and each pad may be electrically connected to a plurality of connecting wires located in the peripheral area PA. The connecting wires may electrically connect signal lines arranged in the display area DA with the pads. The signal lines may be data lines DLs or scan lines SLs (see, e.g., FIG. 5).

FIG. 5 is an equivalent circuit diagram of a pixel circuit PC included in the display panel 10 shown in FIG. 4 according to an embodiment. The pixel circuit PC may be electrically connected to the display element, and one display element may correspond to one pixel PX. In FIG. 5, an organic light emitting diode OLED is shown as a display element as an example. The display element may emit red, green, or blue light.

The pixel circuit PC may include a first transistor T1, a second transistor T2, and a storage capacitor Cst. The second transistor T2, as a switching transistor, may be connected to a scan line SL and a data line DL and may be turned on by a switching signal received from the scan line SL to transmit a data signal received from the data line DL to the first transistor T1. One end of the storage capacitor Cst may be electrically connected to the second transistor T2, and the other end thereof may be electrically connected to the driving voltage line PL. The storage capacitor Cst may store a voltage corresponding to a difference between a voltage received from the second transistor T2 and a driving power voltage ELVDD supplied to the driving voltage line PL.

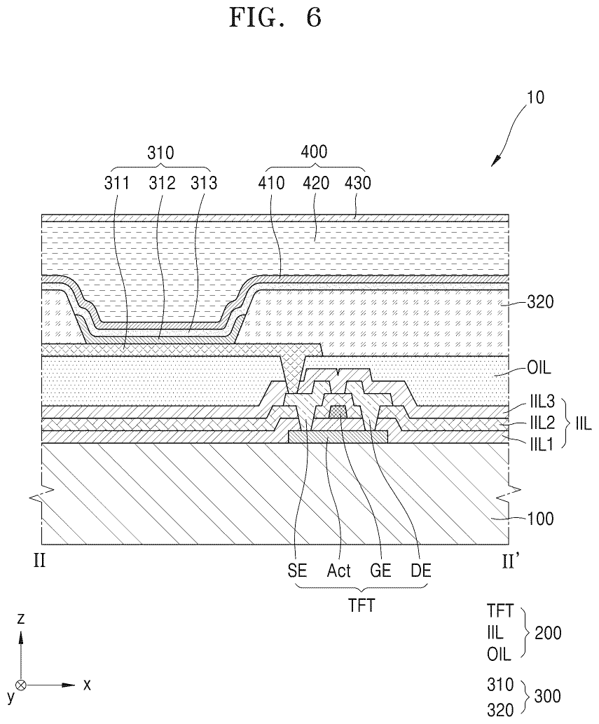

The first transistor T1, as a driving transistor, may be connected to the driving voltage line PL and the storage capacitor Cst and may be configured to control the magnitude of a driving current flowing from the driving voltage line PL to the organic light emitting diode OLED in response to the voltage stored in the storage capacitor Cst. The organic light-emitting diode OLED may emit light having a luminance according to (or determined by) the driving current. A counter electrode 313 (see, e.g., FIG. 6) of the organic light emitting diode OLED may receive an electrode power voltage ELVSS.

Although FIG. 5 shows an embodiment in which the pixel circuit PC includes two transistors and one storage capacitor, the present disclosure is not limited thereto. For example, the number of transistors, the number of storage capacitors, and connection relationship therebetween may vary in accordance with a design of the pixel circuit PC.

FIG. 6 is a schematic cross-sectional view taken along the line II-II′ in FIG. 4. As shown in FIG. 6, the display panel 10 may include a substrate 100, a pixel circuit layer 200, a display element layer 300, and an encapsulation layer 400.

The substrate 100 may include glass, a metal, or a polymer resin. The substrate 100 may have flexible or bendable properties. For example, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. Various changes may be made to the substrate 100, for example, the substrate 100 may have a multilayer structure including two layers including the polymer resin and a barrier layer disposed between the two layers and including an inorganic material. The inorganic material may include silicon oxide (SiO_{X}), silicon nitride (SiN_{X}), silicon oxynitride (SiO_{X}N_{Y}), and the like but is not limited thereto.

A pixel circuit layer 200 may be disposed on the substrate 100. The pixel circuit layer 200 may include a thin film transistor TFT, an inorganic insulating layer IIL, and an organic insulating layer OIL. The thin film transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, FIG. 6 shows one thin film transistor TFT, and the thin film transistor TFT may correspond the above-described driving thin film transistor T1 (see, e.g., FIG. 5).

The semiconductor layer Act may be disposed on the substrate 100. The semiconductor layer Act may include poly silicon. In another embodiment, the semiconductor layer Act may include amorphous silicon, an oxide semiconductor, an organic semiconductor, or the like. The semiconductor layer Act may have a channel region and a source region and a drain region respectively located at both sides (e.g., at opposite sides) of the channel region.

The gate insulating layer IIL1 may be disposed on the semiconductor layer Act and the substrate 100. The gate insulating layer IIL1 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ). The zinc oxide (ZnO_{X}) may include zinc oxide (ZnO) and/or zinc peroxide (ZnO₂).

The gate electrode GE may be disposed on the gate insulating layer IIL1. Because the gate insulating layer IIL1 is disposed between the semiconductor layer Act and the gate electrode GE, the gate insulating layer IIL1 insulates between the semiconductor layer Act and the gate electrode GE. The gate electrode GE may overlap the channel region of the semiconductor layer Act. The gate electrode GE may include a low-resistance metallic material. The gate electrode GE may include a conductive material, such as molybdenum (Mo), aluminum (Al), copper (Cu), and titanium (Ti) and may have a single-layer or multi-layer structure including such a conductive material.

The first interlayer insulating layer IIL2 may be disposed on the gate electrode GE and the gate insulating layer IIL1. The first interlayer insulating layer IIL2 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ).

The source electrode SE and the drain electrode DE may be disposed on the first interlayer insulating layer IIL2. Each of the source electrode SE and the drain electrode DE may be connected to the semiconductor layer Act via a contact hole (e.g., a contact opening) formed in the gate insulating layer IIL1 and the first interlayer insulating layer IIL2. At least one of the source electrode SE and the drain electrode DE may include a conductive material, such as molybdenum (Mo), aluminum (Al), copper (Cu), or titanium (Ti) and may have a single-layer or multi-layer structure including such a conductive material. For example, at least one of the source electrode SE and the drain electrode DE may have a multi-layer structure of Ti/Al/Ti.

The second interlayer insulating layer IIL3 may be disposed on the source electrode SE, the drain electrode DE, and the first interlayer insulating layer IIL2. The second interlayer insulating layer IIL3 may include an inorganic insulating material, such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOₓ).

The organic insulating layer OIL may be disposed on the second interlayer insulating layer IIL3. The organic insulating layer OIL may substantially planarize the upper surface of the pixel circuit layer 200. For example, the organic insulating layer OIL may include an organic material, such as an acrylic compound, benzocyclobutene (BCB), or hexamethyldisiloxane (HMDSO). Although the organic insulating layer OIL is illustrated as being a single layer in FIG. 6, the organic insulating layer OIL may have a multilayer structure, and various modifications may be made.

The display element layer 300 may be disposed on the pixel circuit layer 200. The display element layer 300 may include a display element 310 and a pixel-defining layer 320. The display element 310 may be electrically connected to the thin film transistor TFT. The display element 310 may be, for example, an organic light emitting diode including a pixel electrode 311, a counter electrode 313, and an intermediate layer 312 disposed therebetween and including an emission layer. Electrically connecting the display element 310 to the thin film transistor TFT may be understood as electrically connecting the pixel electrode 311 of the organic light emitting diode to the thin film transistor TFT.

The pixel electrode 311 may be electrically connected to the thin film transistor TFT by contacting either the source electrode SE or the drain electrode DE through a contact hole (e.g., a contact opening) formed in the second interlayer insulating layer IIL3 and the organic insulating layer OIL. The pixel electrode 311 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. The pixel electrode 311 may further include a film formed of ITO, IZO, ZnO or In₂O₃ on the upper or lower surface of the reflective layer.

The pixel-defining layer 320 may cover edges of the pixel electrode 311. The pixel-defining layer 320 may include a pixel opening, and the pixel opening may overlap the pixel electrode 311. The pixel opening may define an emitting area of light emitted from (e.g., a light emitting area of) the display element 310. The pixel-defining layer 320 may include an organic insulating material and/or an inorganic insulating material. The pixel-defining layer 320 may include a light shielding (or blocking) material.

The intermediate layer 312 may be disposed on the pixel electrode 311 and the pixel-defining layer 320. The intermediate layer 312 may be disposed in at least a part of the pixel opening formed in the pixel-defining layer 320. The intermediate layer 312 may include a low-molecular-weight or high-molecular-weight material. In an embodiment in which the intermediate layer 312 includes a low-molecular-weight material, the intermediate layer 312 may have a structure including a hole injection layer (HIL), a hole transport layer (HTL), an emission layer (EML), an electron transport layer (ETL), an electron injection layer (EIL), or the like as a single-layer structure or as a multi-layer structure in which the layers are stacked in a complex configuration, by vacuum deposition, etc. In an embodiment in which the intermediate layer 312 includes a polymer material, the intermediate layer 312 may have a structure including a HTL and an EML. In such an embodiment, the HTL may include poly(3,4-ethylenedioxythiophene) (PEDOT), and the EML may include a polymer material, such as polyphenylene vinylene (PPV) and polyfluorene. The intermediate layer 312 may be formed by screen printing, inkjet printing, laser induced thermal imaging (LITI), or the like. However, the intermediate layer 312 is not limited thereto and may also have various suitable structures. The intermediate layer 312 may include an integrated layer (e.g., may be a common layer) formed on the plurality of pixel electrodes 311 or a patterned layer corresponding to each of the plurality of pixel electrodes 311.

The counter electrode 313 may be disposed on the intermediate layer 312 and the pixel-defining layer 320. The counter electrode 313 may be integrally formed for the plurality of organic light emitting diodes (e.g., the counter electrode 313 may be a common layer or common electrode) to correspond to the plurality of pixel electrodes 311. The counter electrode 313 may include a transparent conductive layer formed of ITO, In₂O₃, or IZO and may also include a semi-transparent layer including a metal, such as Al or Ag. For example, the counter electrode 313 may be a semi-transparent layer including Mg or Ag.

Because the display element 310 is easily damaged by external moisture or oxygen, the encapsulation layer 400 may cover the display element 310 to protect the display element 310 from external moisture and oxygen. The encapsulation layer 400 may include a first inorganic encapsulation layer 410, an organic encapsulation layer 420, and a second inorganic encapsulation layer 430 as shown in FIG. 6.

The first inorganic encapsulation layer 410 may cover the counter electrode 313 and may include silicon oxide (SiO_{X}), silicon nitride (SiN_{X}), silicon oxynitride (SiO_{X}N_{Y}), and/or the like. In some embodiments, other layers, such as a capping layer, may be disposed between the first inorganic encapsulation layer 410 and the counter electrode 313. Because the first inorganic encapsulation layer 410 may be formed along the underlying structure, the upper surface thereof may not be planarized (e.g., may not be flat) as shown in FIG. 6. The organic encapsulation layer 420 covers the first inorganic encapsulation layer 410 and may different from the first inorganic encapsulation layer 410, substantially planarize the upper surface thereof. The organic encapsulation layer 420 may include at least one material selected from polyethylene terephthalate, polyethylene naphthalate, polycarbonate, polyimide, polyethylene sulfonate, polyoxymethylene, polyarylate, and hexamethyldisiloxane. The second inorganic encapsulation layer 430 covers the organic encapsulation layer 420 and may include silicon oxide (SiO_{X}), silicon nitride (SiN_{X}), silicon oxynitride (SiO_{X}N_{Y}), and/or the like.

Because the encapsulation layer 400 includes the first inorganic encapsulation layer 410, the organic encapsulation layer 420, and the second inorganic encapsulation layer 430, cracks, even when they occur in the encapsulation layer 400, may not propagate through the multi-layered structure. For example, cracks may not be connected between the first inorganic encapsulation layer 410 and the organic encapsulation layer 420 or between the organic encapsulation layer 420 and the second inorganic encapsulation layer 430. This may prevent or minimize formation of pathways through which external moisture or oxygen can infiltrate into the display panel 10.

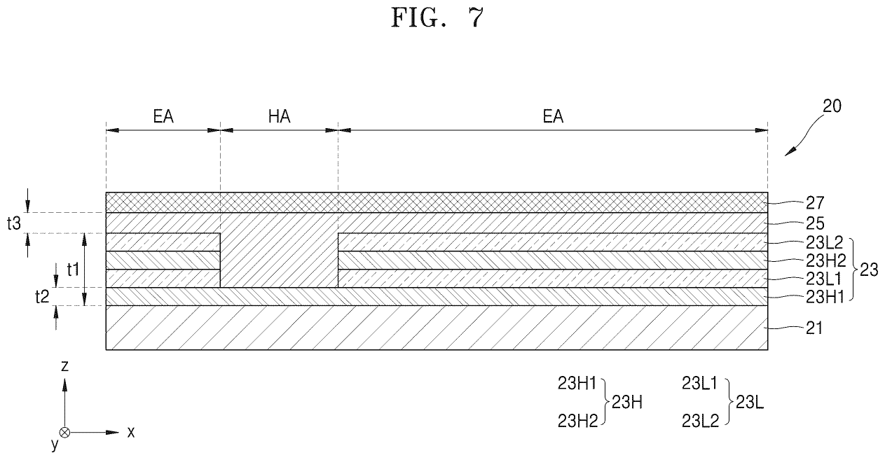

FIG. 7 is a cross-sectional view of the protective layer 20 included in the display device 1 shown in FIG. 3. As shown in FIG. 7, the protective layer 20 may include a cover window 21, an anti-reflection layer 23, a planarization layer 25, and an anti-fingerprint layer 27.

The cover window 21 may be disposed on the display panel 10. For example, the cover window 21 may be disposed on the upper surface of the display panel 10. The cover window 21 may be disposed to cover the upper surface of the display panel 10. An image displayed on (e.g., emitted by) the display panel 10 may be provided to a user through a transparent cover window 21.

The cover window 21 may protect the upper surface of the display panel 10. The cover window 21 may have high strength and hardness to protect the display panel 10 from external impacts. The cover window 21 may have a high transmittance to transmit light emitted by the display panel 10 and a small thickness to reduce or minimize a weight of the display device 1. The cover window 21, defining the exterior appearance of the display device 1, may have planar and curved surfaces corresponding to a shape of the display device 1.

The cover window 21 may be a flexible window. The cover window 21 may be easily bent by an external force without generating cracks or the like, thereby protecting the display panel 10. The cover window 21 may include glass or plastic. In an embodiment, the cover window 21 may include ultra-thin glass (UTG) having enhanced strength by chemical or thermal tempering. The cover window 21 may include a polymer resin.

An adhesive member may be disposed between the display panel 10 and the cover window 21. The adhesive member may include at least one of an optical clear resin (OCR), an optical clear adhesive (OCA), and a pressure sensitive adhesive (PSA). The adhesive member may bond the display panel 10 to the cover window 21.

The anti-reflection layer 23 may be disposed on the cover window 21. The anti-reflection layer 23 may be formed by methods, such as electron-beam (E-beam) vapor deposition, sputtering, thermal deposition, or spin coating. For example, the anti-reflection layer 23 may be formed by sputtering to have a substantially uniform first thickness t1. A base layer, which is a plastic film including a polymer resin, may be disposed between the cover window 21 and the anti-reflection layer 23. For example, the base layer may include at least one polymer resin, such as polyethylene terephthalate (PET), poly(butylene terephthalate) (PBT), polycarbonate (PC), polyethylene naphthalate (PEN), polystyrene (PS), polymethylmethacrylate (PMMA), polyvinylchloride (PVC), polyethersulfone (PES), polypropylene (PP), and polyamide (PA).

The anti-reflection layer 23 may include an anti-reflection material. The anti-reflection material may be a high-refractive-index material and/or a low-refractive-index material, which will be described in more detail below. The anti-reflection layer 23 may reduce reflectance of light incident from the outside. The anti-reflection layer 23 may include at least one high-refractive-index layer 23H and at least one low-refractive-index layer 23L, which are alternately stacked. For example, the anti-reflection layer 23 may include a first high-refractive-index layer 23H1 disposed on the cover window 21, a first low-refractive-index layer 23L1 disposed on the first high-refractive-index layer 23H1, a second high-refractive-index layer 23H2 disposed on the first low-refractive-index layer 23L1, and a second low-refractive-index layer 23L2 disposed on the second high-refractive-index layer 23H2. Also, various modifications may be made to the first low-refractive-index layer, the first high-refractive-index layer, the second low-refractive-index layer, and the second high-refractive-index layer, which are sequentially stacked on the cover window 21, and the number of the high-refractive-index layers 23Hs and/or the number of the low-refractive-index layers 23Ls may be decreased or increased.

The first high-refractive-index layer 23H1 may be disposed on the cover window 21. The first high-refractive-index layer 23H1 may include a high-refractive-index material. According to an embodiment, the first high-refractive-index layer 23H1 may include titanium (Ti), aluminum (Al), indium (In), or any combination thereof. The first high-refractive-index layer 23H1 may include a metal oxide. The first high-refractive-index layer 23H1 may include titanium oxide, aluminum oxide, indium oxide, or any combination thereof. For example, the first high-refractive-index layer 23H1 may include TiO₂, Al₂O₃, In₂O₃, or any combination thereof. In another embodiment, the first high-refractive-index layer 23H1 may include a metalloid, such as silicon (Si), or may include a metalloid oxide and/or a metalloid nitride. For example, the first high-refractive-index layer 23H1 may include silicon nitride (SiN).

The first high-refractive-index layer 23H1 may have a refractive index of about 1.7 or more, for example, may be in a range of about 1.7 to about 3.0. The refractive index of the first high-refractive-index layer 23H1 with respect to light having a wavelength of approximately 550 nm may be in a range of about 1.7 to about 3.0. For example, the first high-refractive-index layer 23H1 may have a refractive index of about 2.4 by including TiO₂, a refractive index of about 1.9 by including Al₂O₃, or a refractive index of about 1.9 by including In₂O₃.

The first low-refractive-index layer 23L1 may be disposed on the first high-refractive-index layer 23H1. The first low-refractive-index layer 23L1 may include a low-refractive-index material. The first low-refractive-index layer 23L1 may include a metal or a metalloid and/or may include an organic material. According to an embodiment, the first low-refractive-index layer 23L1 may include an acrylic compound, silicon, magnesium, or any combination thereof. The first low-refractive-index layer 23L1 may include a metalloid oxide, a metal fluoride, or plastic.

The refractive index of the first low-refractive-index layer 23L1 may be lower than that of the first high-refractive-index layer 23H1. The refractive index of the first low-refractive-index layer 23L1 may be about 1.6 or less, for example, may be in a range of about 1.3 to about 1.6. The refractive index of the first low-refractive-index layer 23L1 with respect to light having a wavelength of approximately 550 nm may be in a range of about 1.3 to about 1.6. For example, the first low-refractive-index layer 23L 1 may have a refractive index of about 1.45 by including SiO₂, a refractive index of about 1.38 by including MgF₂, or a refractive index of about 1.49 by including polymethylmethacrylate (PMMA).

The second high-refractive-index layer 23H2 may be disposed on the first low-refractive-index layer 23L1. The second high-refractive-index layer 23H2 may include a high-refractive-index material. The second high-refractive-index layer 23H2 may include titanium (Ti), aluminum (Al), indium (In), or any combination thereof. The second high-refractive-index layer 23H2 may include a metal oxide. The second high-refractive-index layer 23H2 may include titanium oxide, aluminum oxide, indium oxide, or any combination thereof. For example, the second high-refractive-index layer 23H2 may include TiO₂, Al₂O₃, In₂O₃, or any combination thereof. In another embodiment, the second high-refractive-index layer 23H2 may include a metalloid, such as silicon (Si) or may include a metalloid oxide and/or a metalloid nitride. For example, the second high-refractive-index layer 23H2 may include silicon nitride (SiN).

The second high-refractive-index layer 23H2 may have a refractive index of about 1.7 or more, for example, in a range of about 1.7 to about 3.0. The refractive index of the second high-refractive-index layer 23H2 with respect to light having a wavelength of approximately 550 nm may be in a range of about 1.7 to about 3.0. For example, the second high-refractive-index layer 23H2 may have a refractive index of about 2.4 by including TiO₂, a refractive index of about 1.9 by including Al₂O₃, or a refractive index of about 1.9 by including In₂O₃. The second high-refractive-index layer 23H2 may include a substantially same material as that included in the first high-refractive-index layer 23H1.

The second low-refractive-index layer 23L2 may be disposed on the second high-refractive-index layer 23H2. The second low-refractive-index layer 23L2 may include a low-refractive-index material. The second low-refractive-index layer 23L2 may include a metal or a metalloid and/or may include an organic material. According to an embodiment, the second low-refractive-index layer 23L2 may include an acrylic compound, silicon, magnesium, or any combination thereof. The second low-refractive-index layer 23L2 may include a metalloid oxide, a metal fluoride, or plastic.

The refractive index of the second low-refractive-index layer 23L2 may be lower than that of the second high-refractive-index layer 23H2. The refractive index of the second low-refractive-index layer 23L2 may be about 1.6 or less, for example, in a range of about 1.3 to about 1.6. The refractive index of the second low-refractive-index layer 23L2 with respect to light having a wavelength of approximately 550 nm may be in a range of about 1.3 to about 1.6. For example, the second low-refractive-index layer 23L2 may have a refractive index of about 1.45 by including SiO₂, a refractive index of about 1.38 by including MgF₂, or a refractive index of about 1.49 by including polymethylmethacrylate (PMMA). The second low-refractive-index layer 23L2 may include a substantially same material as the included in the first low-refractive-index layer 23L1.

As described above, the anti-reflection layer 23 may have a structure in which at least one high-refractive-index layer 23H and at least one low-refractive-index layer 23L are alternately stacked. By adjusting the thickness and refractive index of each of the high-refractive-index layers 23Hs and the low-refractive-index layers 23Ls, light beams reflected at interfaces between the layers may destructively interfere with each other so that the anti-reflection layer 23 may reduce reflectance of light incident from the outside. As a result, high visibility of an image displayed on the display device 1 may be obtained even when light is incident from the outside.

As the number of the high-refractive-index layers 23Hs and/or the low-refractive-index layers 23Ls increases, a deposition time for forming the anti-reflection layer 23 may increase. As the deposition time increases, the possibility that foreign matter is adsorbed to the cover window 21, the high-refractive-index layer 23H, or the low-refractive-index layer 23L may increase. While the adsorbed foreign matter detaches, the high-refractive-index layer 23H and/or the low-refractive-index layer 23L formed on the foreign matter may also be removed together therewith, and a part of the high-refractive-index layer 23H and/or a part of the low-refractive-index layer 23L formed under the foreign matter may be removed together therewith. Because a part of the high-refractive-index layer 23H and/or a part of the low-refractive-index layer 23L are removed from the anti-reflection layer 23 having a substantially uniform first thickness t1, the anti-reflection layer 23 may have an area with a smaller second thickness t2 than the first thickness t1. An area of the anti-reflection layer 23 having a substantially uniform first thickness t1 may be referred to as flat area EA, and an area having a smaller second thickness t2 than the first thickness t1 due to foreign matter or the like may be referred to as hole area (or open area) HA.

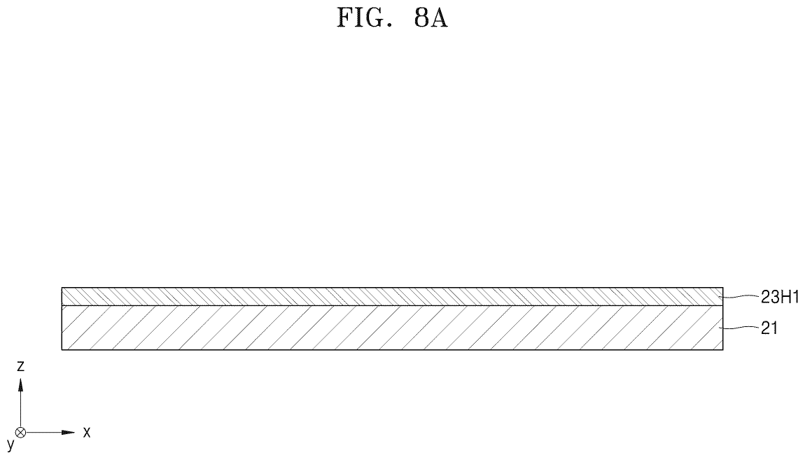

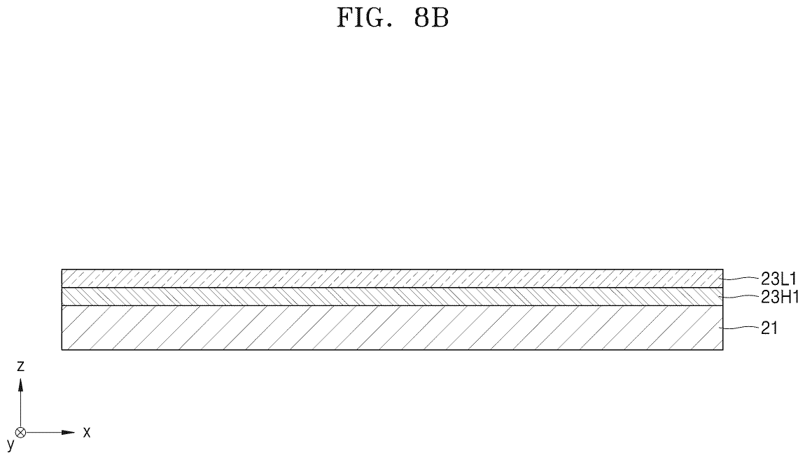

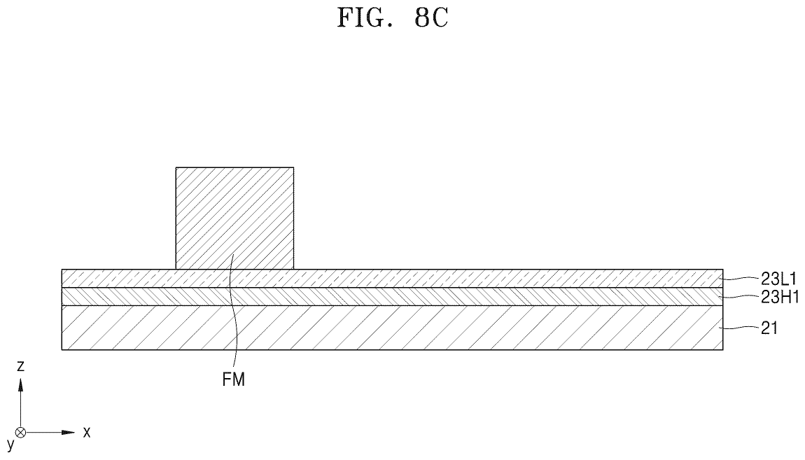

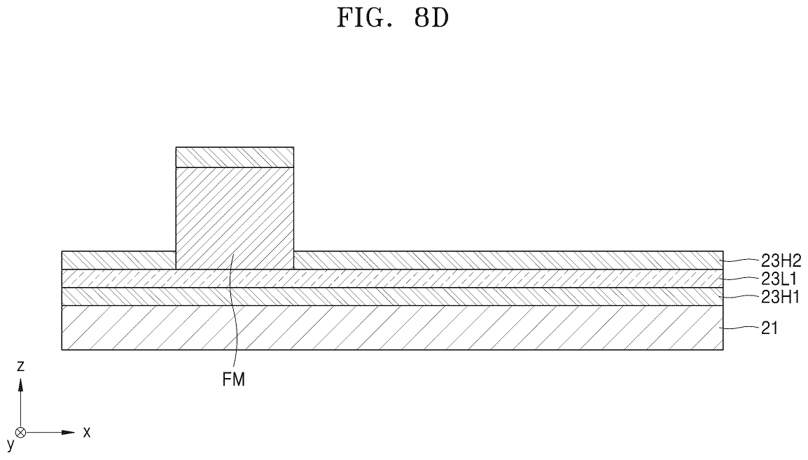

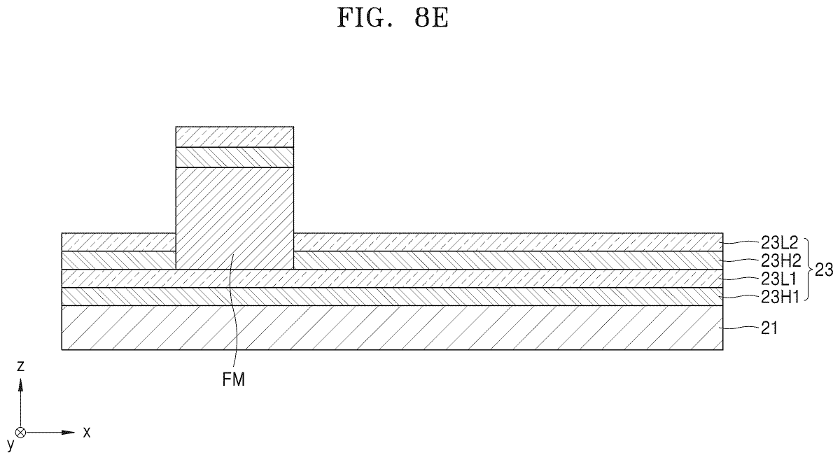

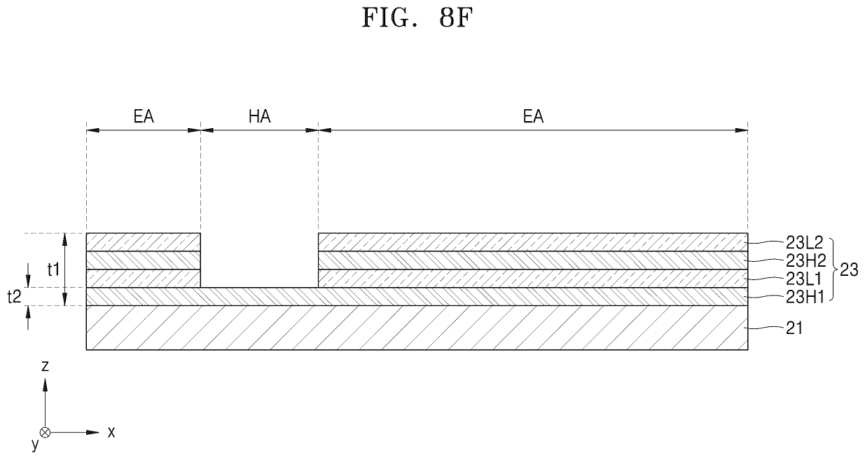

FIGS. 8A to 8F are cross-sectional views schematically showing steps of a process of adsorption and desorption of foreign matter during manufacturing of a protective layer according to an embodiment.

Referring to FIG. 8A, the first high-refractive-index layer 23H1 may be formed on the cover window 21 by deposition using sputtering.

Referring to FIG. 8B, the first low-refractive-index layer 23L1 may be formed on the first high-refractive-index layer 23H1 by deposition using sputtering.

Referring to FIG. 8C, foreign matter FM may be adsorbed (e.g., may be incidentally adsorbed) onto the first low-refractive-index layer 23L1 during deposition by sputtering.

Referring to FIG. 8D, the second high-refractive-index layer 23H2 may be formed on the first low-refractive-index layer 23L1 and the foreign matter FM by deposition using sputtering.

Referring to FIG. 8E, the second low-refractive-index layer 23L2 may be formed on the second high-refractive-index layer 2 3H2 and the foreign matter FM by deposition using sputtering.

Referring to FIG. 8F, when the foreign matter FM detaches, not only the second high-refractive-index layer 23H2 and the second low-refractive-index layer 23L2 formed on the foreign matter FM are removed but also the first low-refractive-index layer 23L1 under the foreign matter FM may be removed together therewith. The anti-reflection layer 23 has the flat area EA having the substantially uniform first thickness t1 and the hole area (or open area) HA having the second thickness t2 that is smaller than the first thickness t1 because at least a part thereof is removed by the foreign matter FM. Also, the first high-refractive-index layer 23H1 under the foreign matter FM may be removed as a result of detachment of the foreign matter FM, and in this case, the second thickness t2 is 0, and a component under the anti-reflection layer 23 (e.g., cover window 21) may be exposed.

Accordingly, the anti-reflection layer 23 is removed in whole or in part in the hole area HA, and thus, reflectance of light incident from the outside may be relatively high. That is, the function of the anti-reflection layer 23 may be weakened in the hole area HA and glare may occur in the area where a part or all of the anti-reflection layer 23 is absent due to high reflectance of the incident light. This glare may reduce visibility of the image provided by (e.g., emitted from) the display device 1.

Referring back to FIG. 7, the planarization layer 25 may be disposed on the anti-reflection layer 23. The planarization layer 25 may fill the hole area HA in the anti-reflection layer 23. For example, the planarization layer 25 may be disposed on the flat area EA and in the hole area HA in the anti-reflection layer 23. The upper surface of the planarization layer 25 may be substantially flat. The planarization layer 25 may have a substantially uniform third thickness t3 in the flat area EA of the anti-reflection layer 23, but the thickness of the planarization layer 25 may be greater than the third thickness t3 in the hole area HA because the planarization layer 25 fills the hole area HA in the anti-reflection layer 23. The third thickness t3 may refer to an interval between the anti-fingerprint layer 27 and the anti-reflection layer 23, which will be described in more detail below.

According to an embodiment, the planarization layer 25 may be formed by a spray coating method. That is, the possibility of adsorption of foreign matter FM may be eliminated while the planarization layer 25 is formed.

The planarization layer 25 may include a low-refractive-index material. The planarization layer 25 may include a metal or a metalloid and/or may include an organic material. According to an embodiment, the planarization layer 25 may include magnesium, silicon, calcium, or any combination thereof. The planarization layer 25 may include a metalloid oxide, a metal fluoride, or a metal carbonate. For example, the planarization layer 25 may include MgF₂, SiO₂, CaCO₃, or any combination thereof.

In an embodiment, the refractive index of the planarization layer 25 may be smaller than that of the high-refractive-index layer 23H. The refractive index of the planarization layer 25 may be equal to or smaller than that of the low-refractive-index layer 23L. The refractive index of the planarization layer 25 may be about 1.6 or less, for example, in a range of about 1.3 to about 1.6. The refractive index of the planarization layer 25 with respect to light having a wavelength of approximately 550 nm may be in a range of about 1.3 to about 1.6. For example, the planarization layer 25 may have a refractive index of about 1.45 by including SiO₂, a refractive index of about 1.38 by including MgF₂, or a refractive index of about 1.5 by including CaCO₃.

Because the planarization layer 25 includes a low-refractive-index material, the extent to which reflectance of light incident in the hole area HA increases may not be significant even if all of the anti-reflection layer 23 is removed by the foreign matter FM in the hole area HA.

According to an embodiment, the first thickness t1 of the anti-reflection layer 23 may be about 250 nm or less. For example, the first thickness t1 of the anti-reflection layer 23 may be in a range of about 120 nm to about 240 nm. When the first thickness t1 of the anti-reflection layer 23 exceeds the above-described range, the high-refractive-index layer 23H and/or the low-refractive-index layer 23L remaining without being removed when the anti-reflection layer 23 is partially removed during detachment of the foreign matter FM, are sufficient even if the planarization layer 25 is absent. As a result, the property of reducing light reflectance may be maintained. However, when the first thickness t1 of the anti-reflection layer 23 should be adjusted within the above-described range for weight minimization of the display device 1, due to other components for light-emitting characteristics and due to relationships with other components for protection characteristics, all of the anti-reflection layer 23 under the adsorbed foreign matter FM may be removed with high probability while the anti-reflection layer 23 is removed during detachment of the adsorbed foreign matter FM. Therefore, when the anti-reflection layer 23 is relatively thin, that is, when the above-described range is satisfied, reflectance of light may be efficiently reduced by the planarization layer 25.

According to an embodiment, the third thickness t3 of the planarization layer 25, that is, the interval between the anti-fingerprint layer 27 and the anti-reflection layer 23, may be in a range of about 60 nm to about 120 nm. For example, the third thickness t3 of the planarization layer, that is, the interval between the anti-fingerprint layer 27 and the anti-reflection layer 23, may be in a range of about 66 nm to about 116 nm, in a range of about 75 nm to about 105 nm, or in a range of about 85 nm to about 100 nm. When the third thickness t3 of the planarization layer, that is, the interval between the anti-fingerprint layer 27 and the anti-reflection layer 23, satisfies any of the above-described ranges, light reflectance may be effectively reduced. When the third thickness t3 is out of the above-described ranges, the effect of reducing light reflectance may deteriorate.

In an embodiment, the reflectance of the protective layer 20 may be about 5% or less. The protective layer 20 may have a reflectance of about 5% or less, about 4% or less, about 3% or less, or about 2% or less in a region corresponding to the flat area EA, and a reflectance of about 6% or less, about 5% or less, about 4.5% or less, or about 4% or less in a region corresponding to the hole area HA. Therefore, the protective layer 20 may exhibit satisfactory optical characteristics even in the hole area HA from which a part or all of the anti-reflection layer 23 is removed. The above-described reflectance may be a reflectance of light having a wavelength in a range of about 450 nm to about 700 nm, in a range of about 500 nm to about 600 nm, or about 550 nm. The reflectance may be a reflectance measured by a specular component included (SCI) mode.

The anti-fingerprint layer 27 may be disposed on the planarization layer 25. For example, the planarization layer 25 may be disposed between the anti-reflection layer 23 and the anti-fingerprint layer 27. The anti-fingerprint layer 27 may be disposed on the surface of the protective layer 20. The anti-fingerprint layer 27 may prevent the surface of the protective layer 20 from wearing down. The anti-fingerprint layer 27 may include a perfluorinated compound. For example, the anti-fingerprint layer 27 may include perfluoropolyether (PFPE) but is not limited thereto. Perfluoropolyether (PFPE) has a structure in which an ether bond with high flexibility is introduced into rigid and short perfluoroalkyl chains. Therefore, perfluoropolyether (PFPE) has soft amorphous characteristics, excellent anti-fingerprint properties, and superior slip properties.

The anti-fingerprint layer 27 may be formed by methods, such as electron-beam (E-beam) vapor deposition, sputtering, thermal deposition, or spin coating.

A light-shielding layer may be disposed between the cover window 21 and the anti-reflection layer 23. The light-shielding layer may be located along edges of the protective layer 20. For example, the light-shielding layer may be arranged to overlap the peripheral area PA of the display panel 10 described above with reference to FIG. 4. The light-shielding layer may conceal wiring or circuits located in the peripheral area PA of the display panel 10 from external view and may prevent light leakage from the display panel 10. A region where the light-shielding layer is arranged may be a bezel area of the display device 1. The light-shielding layer may have a single-layer or multi-layer structure and may include at least one of an acrylic compound, urethane, epoxy, polyester, and epoxy ether.

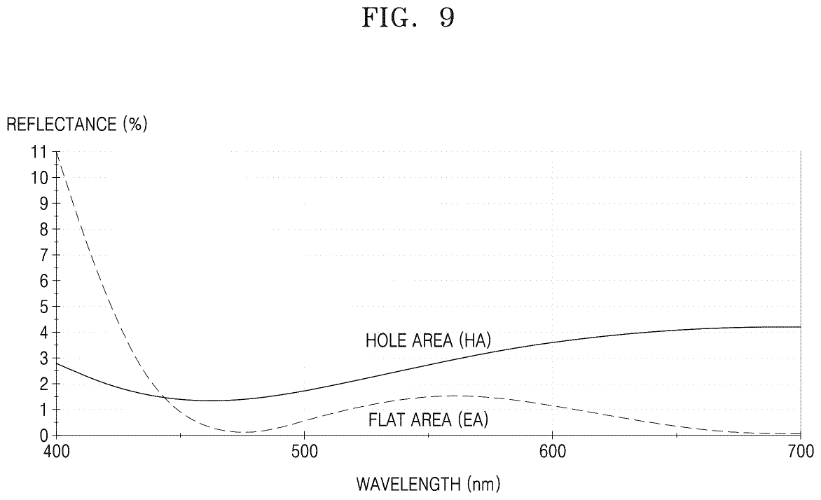

FIG. 9 is a graph showing reflectance of the protective layer 20 with respect to wavelength according to an embodiment. In more detail, FIG. 9 is a graph showing results of comparison of reflectance between the flat area EA and the hole area HA in the protective layer 20 in which the anti-reflection layer 23 having a thickness of 250 nm (i.e., the first thickness t1) in the flat area EA is completely removed (i.e., the second thickness t2=0) from the hole area HA, and the planarization layer 25 including MgF₂ is formed to have a thickness of 90 nm (i.e., third thickness t3) in flat area EA and fills the hole area HA.

Referring to FIG. 9, the reflectance of light having a wavelength in a range of about 450 nm to about 700 nm is about 2% or less in the flat area EA where the anti-reflection layer 23 is completely formed and a reflectance of light having a wavelength in a range of about 450 nm to about 700 nm is about 5% or less in the hole area HA. Therefore, although at least a part of the anti-reflection layer 23 is removed due to the foreign matter FM, the protective layer 20, according to an embodiment, may effectively suppress the extent to which reflectance of light incident from the outside increases because the protective layer 20 includes the planarization layer 25 to prevent glare. Therefore, visibility of the display device 1 including the protective layer 20 may be improved so that display quality of an electronic device including the display device 1 may be improved.

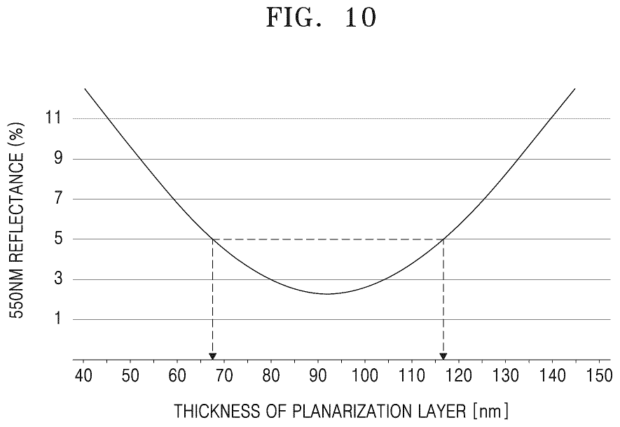

FIG. 10 is a graph showing reflectance of the protective layer 20 with respect to light having a wavelength of 550 nm with respect to thickness of the planarization layer 25 included in the protective layer 20 according to an embodiment. The thickness of the planarization layer 25 refers to the above-described third thickness t3, that is, the interval between the anti-reflection layer 23 and the anti-fingerprint layer 27. In more detail, FIG. 10 shows results of evaluation of protective layers 20 in which only the thickness of the planarization layer 25 was varied as described in FIG. 9.

Referring to FIG. 10, reflectance of light having a wavelength of 550 nm may be effectively reduced when the thickness of the planarization layer 25 is in a range of about 60 nm to about 120 nm.

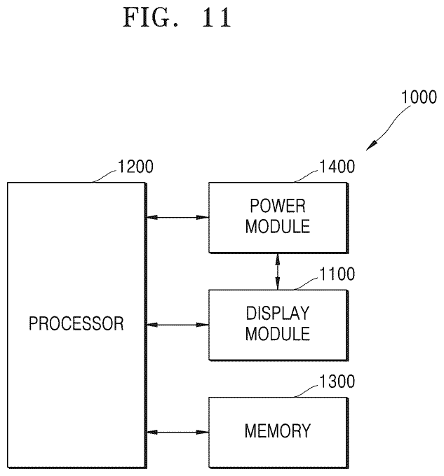

FIG. 11 is a block diagram describing an electronic device 1000 including the display device 1 according to an embodiment.

The display device 1, according to an embodiment, may be applied to various electronic devices 1000. The electronic device 1000 according to an embodiment includes the above-described display device 1 and may further include other modules or devices having additional functions in addition to the display device 1.

Referring to FIG. 11, the electronic device 1000, according to an embodiment, may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data information for operation of the processor 1200 or the display module 1100. Upon execution of an application stored in the memory 1300 by the processor 1200, image data signals and/or input control signals are transmitted to the display module 1100, and the display module 1100 may be configured to process the received signals and output (e.g., emit) image information via a display screen.

The power module 1400 may include a power supply module, such as a power adapter or a battery device, and a power conversion module configured to convert the power supplied by the power supply module to generate power required for the operation of the electronic device 1000.

At least one of the above-described components of the electronic device 1000 may be included in the display device 1 according to the embodiments described above. In other embodiments, some of the individual modules functionally included in a single module may be included in the display device 1, and others may be provided separately from the display device 1. For example, the display device 1 may include the display module 1100, and the processor 1200, the memory 1300, and the power module 1400 may be provided in the form of other devices in the electronic device 1000 other than the display device 1.

According to an embodiment, the electronic device 1000 may be one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle instrument cluster, a vehicle center information display (CID), a vehicle head-up display, a room mirror display, a video wall, theater, or stadium screen including multiple displays tiled together, a light therapy device, and a signage.

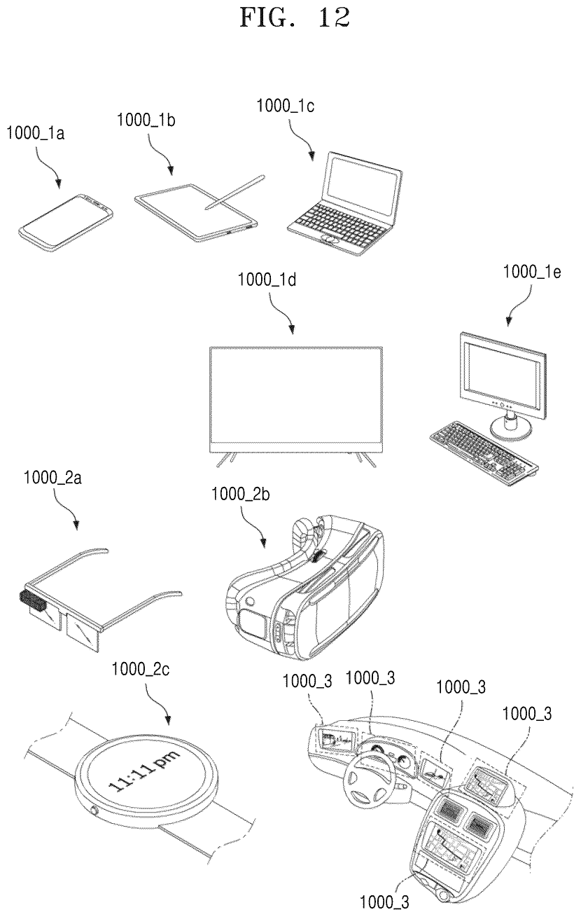

FIG. 12 shows schematic diagrams of electronic devices 1000 according to various embodiments.

Referring to FIG. 12, various types of electronic devices 1000 to which the display device 1, according to embodiments, is applied may include not only image display electronic devices, such as smartphones 1000_1a, tablet PCs 1000_1b, laptop computers 1000_1c, TVs 1000_1d, and desktop monitors 1000_1e, but also wearable electronic devices including a display module, such as smart glasses 1000_2a, head-mounted displays 1000_2b, and smartwatches 1000_2c, and vehicle electronic devices 1000_3 including a display module, such as instrument clusters, information displays (CID) placed in the center fascia and dashboard, and room mirror displays.

Because the above-described protective layer includes the planarization layer including the low-refractive-index material in the hole area, from which a part or all of the anti-reflection layer is removed, by using a spray coating method that reduces the risk of foreign matter adsorption, glare caused by relatively high light reflectance may be reduced. Therefore, visibility of the display device including the protective layer may be improved, and display quality of the electronic device including the display device may be improved.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A protective layer comprising:
a cover window;
an anti-reflection layer on the cover window, the anti-reflection layer having a flat area having a first thickness and an open area having a second thickness that is smaller than the first thickness; and
a planarization layer on the anti-reflection layer and filling the open area.

2. The protective layer of claim 1, further comprising an anti-fingerprint layer on the planarization layer.

3. The protective layer of claim 2, wherein the planarization layer is in direct contact with the anti-fingerprint layer.

4. The protective layer of claim 2, wherein an interval between the anti-reflection layer and the anti-fingerprint layer is in a range of 60 nm to 120 nm.

5. The protective layer of claim 1, wherein the first thickness is 250 nm or less.

6. The protective layer of claim 1, wherein the planarization layer has a refractive index in a range of 1.3 to 1.6.

7. The protective layer of claim 1, wherein the planarization layer comprises magnesium, silicon, calcium, or a combination thereof.

8. The protective layer of claim 1, wherein the anti-reflection layer comprises a high-refractive-index layer and a low-refractive-index layer, which are alternately stacked on each other.

9. The protective layer of claim 8, wherein the anti-reflection layer comprises a first high-refractive-index layer, a first low-refractive-index layer, and a second high-refractive-index layer sequentially stacked in the flat area, and at least one of the first high-refractive-index layer, the first low-refractive-index layer, and the second high-refractive-index layer is not in the open area, or
wherein the anti-reflection layer comprises a first low-refractive-index layer, a first high-refractive-index layer and a second low-refractive-index layer sequentially stacked in the flat area, and at least one of the first low-refractive-index layer, the first high-refractive-index layer, and the second low-refractive-index layer is not in the open area.

10. The protective layer of claim 8, wherein a refractive index of the planarization layer is smaller than a refractive index of the high-refractive-index layer.

11. The protective layer of claim 8, wherein the high-refractive-index layer has a refractive index of 1.7 or more.

12. The protective layer of claim 8, wherein the high-refractive-index layer comprises titanium, aluminum, indium, or a combination thereof.

13. The protective layer of claim 8, wherein the low-refractive-index layer has a refractive index of 1.6 or less.

14. The protective layer of claim 8, wherein the low-refractive-index layer comprises an acrylic compound, silicon, magnesium, or a combination thereof.

15. The protective layer of claim 1, wherein reflectance of light having a wavelength in a range of 450 nm to 700 nm incident on the open area is 6% or less.

16. A method of manufacturing a protective layer, the method comprising:
forming an anti-reflection layer by depositing an anti-reflection material on a cover window; and
forming a planarization layer on a flat area of the anti-reflection layer having a first thickness and in an open area in the anti-reflection layer having a second thickness that is smaller than the first thickness by a spray coating method.

17. A display device comprising:
a display panel; and
a protective layer on the display panel, the protective layer comprising:
a cover window;
an anti-reflection layer on the cover window, the anti-reflection layer having a flat area having a first thickness and an open area having a second thickness that is smaller than the first thickness; and
a planarization layer on the anti-reflection layer and filling the open area.

18. The display device of claim 17, wherein the display panel is configured to emit light in a direction toward the protective layer.

19. An electronic device comprising:
the display device of claim 17; and
a processor configured to transmit signals to the display device.

20. The electronic device of claim 19, wherein the electronic device is one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle instrument cluster, a vehicle center information display (CID), a vehicle head-up display, a room mirror display, a video wall, theater, or stadium screen including multiple displays tiled together, a light therapy device, and a signage.
